(19) United States
(12) Patent Application Publication
(10) Pub. No.: US 2023/0207316 A1
(43) Pub. Date: Jun. 29, 2023

(54) FILM FORMING METHOD AND FILM FORMING APPARATUS

(71) Applicant: Tokyo Electron Limited, Tokyo (JP)

(72) Inventor: Koji NEISHI, Nirasaki-City (JP)

(21) Appl. No.: 18/146,535

(22) Filed: Dec. 27, 2022

(30) Foreign Application Priority Data
Dec. 28, 2021 (JP) 2021-213824

(51) Int. Cl. H01L 21/02; C23C 16/455; C23C 16/40

(52) U.S. Cl. CPC H01L 21/0262; H01L 21/02554; H01L 21/02565; C23C 16/45544; C23C 16/407

(57) ABSTRACT

A film forming method of forming a metal oxide film on a substrate in a processing container, includes: supplying a raw material gas containing an organometallic precursor into the processing container; removing a residual gas remaining in the processing container after the supplying the raw material gas; subsequently, supplying an oxidizing agent that oxidizes the raw material gas into the processing container; removing a residual gas remaining in the processing container after the supplying the oxidizing agent; and supplying a hydrogen-containing reducing gas into the processing container, simultaneously with the supplying the raw material gas or sequentially after the supplying the raw material gas.

### CROSS-REFERENCE TO RELATED APPLICATION

This application is based upon and claims the benefit of priority from Japanese Patent Application No. 2021-213824, filed on Dec. 28, 2021, the entire contents of which are incorporated herein by reference.

### TECHNICAL FIELD

The present disclosure relates to a film forming method and a film forming apparatus.

### BACKGROUND

As a method of forming a metal oxide film, an atomic Layer Deposition (ALD) method in which an organometallic precursor and an oxidizing agent are supplied alternately has been known. Patent Document 1 discloses that individual metal oxide films are sequentially formed when forming a multi-element metal oxide film such as IGZO by the ALD method and that a content ratio of the multi-element metal oxide film in a film thickness direction is changed by changing a frequency of a step of forming a specific metal oxide film.

### PRIOR ART DOCUMENT

### Patent Document

Patent Document 1: Japanese Laid-Open Publication No. 2016-511936

### SUMMARY

According to an embodiment of the present disclosure, a film forming method of forming a metal oxide film on a substrate in a processing container, includes: supplying a raw material gas containing an organometallic precursor into the processing container; removing a residual gas remaining in the processing container after the supplying the raw material gas; subsequently, supplying an oxidizing agent that oxidizes the raw material gas into the processing container; removing a residual gas remaining in the processing container after the supplying the oxidizing agent; and supplying a hydrogen-containing reducing gas into the processing container, simultaneously with the supplying the raw material gas or sequentially after the supplying the raw material gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a timing chart illustrating a gas supply timing in an example of a film forming method according to a first embodiment.

FIG. 2 is a timing chart illustrating a gas supply timing in another example of the film forming method according to the first embodiment.

FIGS. 3A and 3B are diagrams illustrating an effect of reducing impurities in a case where a H₂ gas is supplied.

FIGS. 4A and 4B are diagrams illustrating an effect of reducing generation of H₂O in the case where the H₂ gas is supplied.

FIG. 5 is a timing chart illustrating a gas supply timing in yet another example of the film forming method according to the first embodiment.

FIG. 6 is a timing chart illustrating a gas supply timing in an example of a film forming method according to a second embodiment.

FIG. 7 is a timing chart illustrating a gas supply timing in another example of the film forming method according to the second embodiment.

FIG. 8 is a timing chart illustrating a gas supply timing in yet another example of the film forming method according to the second embodiment.

FIG. 9 is a schematic cross-sectional view illustrating an IGZO film, which is a specific example of a multi-element metal oxide film formed in the second embodiment.

FIG. 10 is a diagram illustrating a relationship between a substrate temperature and a film thickness, and a relationship between the substrate temperature and a concentration of impurities when forming an InOₓ film by a normal ALD method.

FIG. 11 is a diagram illustrating a relationship between a substrate temperature and a film thickness, and a relationship between the substrate temperature and a concentration of impurities when forming a GaOₓ film by a normal ALD method.

FIG. 12 is a diagram illustrating a relationship between a substrate temperature and a film thickness, and a relationship between the substrate temperature and a concentration of impurities when forming a ZnOₓ film by a normal ALD method.

FIG. 13 is a diagram illustrating a state in which a temperature range of an ALD window is transitioned to a low temperature in a case where triethylgallium and a H₂ gas are simultaneously supplied when forming a GaOₓ film.

FIG. 14 is a cross-sectional view illustrating an example of a film forming apparatus used in the film forming method.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Film Forming Method

First, embodiments of a film forming method will be described.

### First Embodiment

In the present embodiment, a metal oxide film is formed by an ALD method in a state where a substrate is accommodated in a processing container.

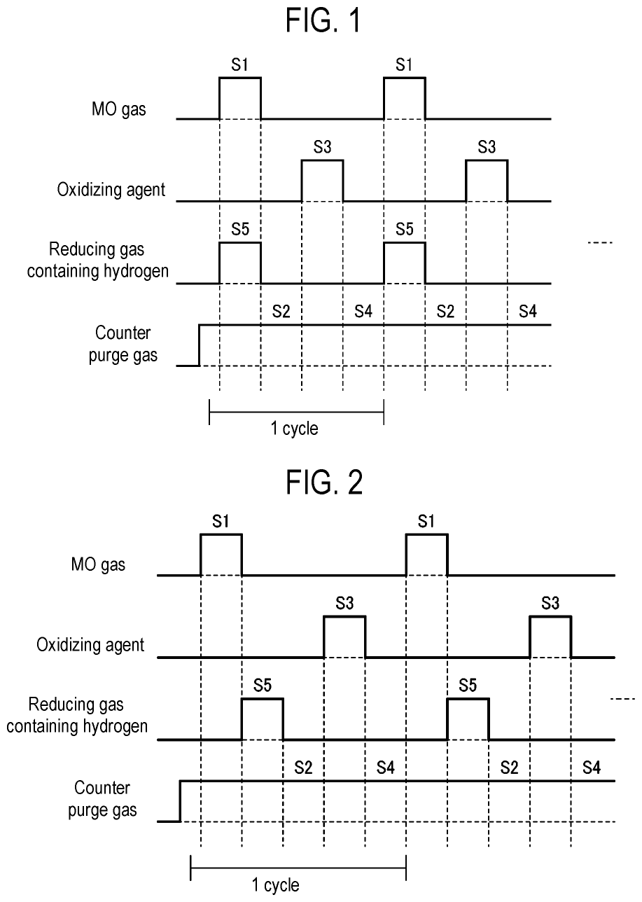

FIG. 1 is a timing chart illustrating a gas supply timing in an example of the film forming method according to a first embodiment. As illustrated in FIG. 1, the film forming method according to the first embodiment includes steps S1, S2, S3, S4, and S5. Then, a sequence of steps S1 to S4 is repeated a desired number of cycles, and step S5 is performed in each cycle.

In step S1, a raw material gas (MO gas) containing an organometallic precursor is supplied into the processing container. The MO gas is generated, for example, by vaporizing an organometallic precursor remaining in a liquid state or solid-state. After performing step S1, in step S2, an interior of the processing container is purged to expel a gas remaining in the processing container. After step S2, in step S3, an oxidizing agent is supplied into the processing container. After performing step S3, in step S4, the interior of the processing container is purged to discharge a gas remaining in the processing container. In step S5, a hydrogen-containing reducing gas, for example, a hydrogen gas (H₂ gas), is supplied into the processing container. The example of FIG. 1 illustrates that the supply of the hydrogen-containing reducing gas in step S5 is performed simultaneously with the supply of the MO gas in step S1. In addition, the example of FIG. 1 illustrates a case where a supply period of the organometallic precursor and a supply period of the hydrogen-containing reducing gas completely coincide with each other. In this case, the expression “simultaneously” also includes a case where these periods partially coincide with each other.

FIG. 2 is a timing chart illustrating a gas supply timing in another example of the film forming method according to the first embodiment. This example illustrates that step S5 is sequentially performed after step S1. Steps S1 to S4 are the same as in the example of FIG. 1.

Hereinafter, the sequences of FIGS. 1 and 2 will be described in more detail.

In step S1, by supplying the MO gas into the processing container, the MO gas is adsorbed onto a substrate surface. The ALD method utilizes a temperature range (ALD window) in which a film formation rate (film thickness) is constant to achieve saturation adsorption.

The organometallic precursor used in step S1 includes an organic ligand bonded to a metal element of a metal oxide film to be formed. The metal element may include indium, gallium, zinc, tin, aluminum, copper, titanium, vanadium, nickel, cobalt, manganese, or tungsten. Further, the organic ligand may include an alkyl group such as CH₃ or C₂H₅. Other organic ligands such as an amino group, an alkoxide group, and a carbonyl group may also be used.

In step S3, by supplying the oxidizing agent into the processing container, the MO gas adsorbed onto the substrate surface is oxidized to form a metal oxide film. The oxidizing agent used in step S3 may be any gas as long as it reacts with the MO gas to form a metal oxide. For example, the oxidizing agent may include an ozone (O₃) gas, an oxygen (O₂) gas, or water vapor (H₂O) gas.

The purging in steps S2 and S4 may be performed by evacuating the interior of the processing container, or by supplying a purge gas into the processing container to expel a residual gas. Alternatively, both the exhaust of the interior of the processing container and the supplying of the purge gas into the processing container may be performed. As the purge gas, a noble gas such as an Ar gas or an inert gas such as a N₂ gas may be used. The examples of FIGS. 1 and 2 illustrate that purging is performed by constantly supplying the purge gas as a counter gas.

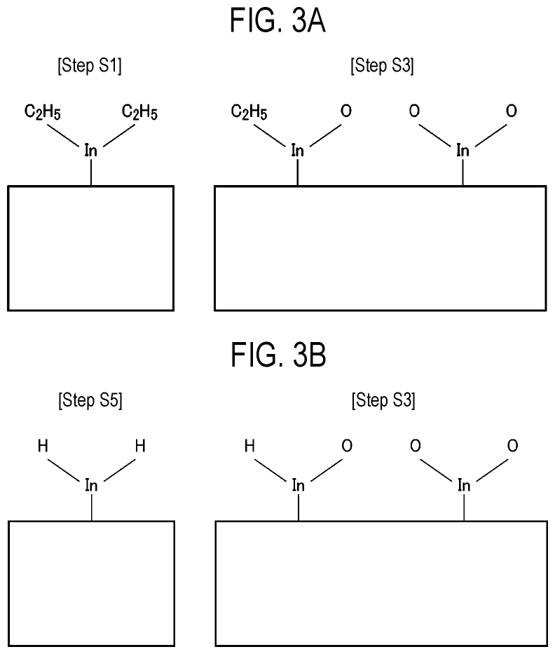

As the hydrogen-containing reducing gas used in step S5, in addition to the H₂ gas, alcohols such as NH₃ or ethanol (C₂H₅OH) may be used. In step S5, by supplying the hydrogen-containing reducing gas, for example, the H₂ gas, both the sequence of FIG. 1 and the sequence of FIG. 2 have the effect of reducing impurities in the film as the hydrogen-containing reducing gas reacts with the organic ligand in the organometallic precursor to desorb the organic ligand. FIGS. 3A and 3B illustrate an example in which triethylindium is used as the organometallic precursor, the O₃ gas is used as the oxidizing agent, and the H₂ gas is used as the hydrogen-containing reducing gas. In a case where the O₃ gas is supplied in step S3 without supplying the H₂ gas after adsorbing triethylindium onto the substrate in step S1, as illustrated in FIG. 3A, an ethyl group (C₂H₅), which is the organic ligand, tends to remain as impurities. On the other hand, by going through step S5 of supplying the H₂ gas, as illustrated in FIG. 3B, since the ethyl group is desorbed from the adsorbed triethylindium and hydrogen termination occurs at that portion, the generation of impurities is reduced in the subsequent oxidation step using the O₃ gas.

Further, in a case where the organic ligand of the organometallic precursor is the alkyl group as described above, since the substrate surface changes from the CHₓ-termination surface to the H-termination surface by going through the step of supplying the hydrogen-containing reducing gas, it may have an improved reactivity with the oxidizing agent and may undergo an oxidation reaction in a short period of time.

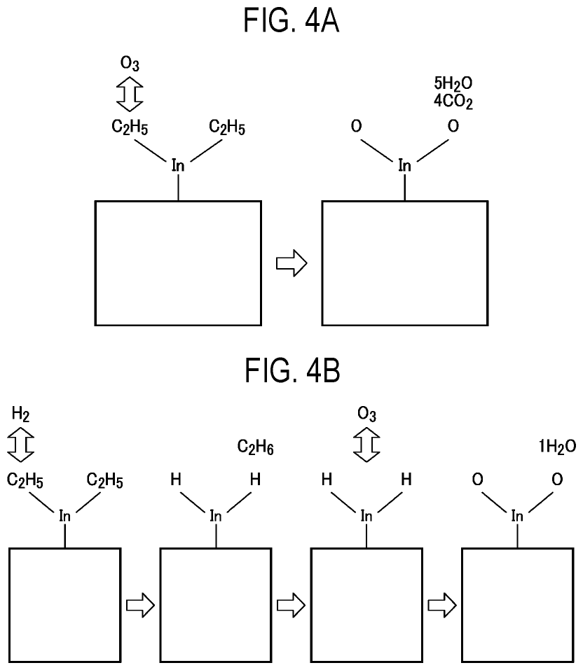

Furthermore, since a large amount of water (H₂O) is generated when the oxidizing agent is supplied to the CHₓ-termination surface, it may take a long time to purge, and during purging, H₂O may be re-adsorbed on the wall surface of a hole formed in the substrate, for example, causing a non-uniform surface reaction, and thus a non-uniform film thickness. On the other hand, by supplying the hydrogen-containing reducing gas so that the substrate surface is the H-termination surface, the generation of H₂O after the supply of the oxidizing agent may be reduced, and thus the above-described problems may be resolved. For example, in a case where the O₃ gas is supplied without supplying the hydrogen-containing reducing gas in a state where triethylindium is vaporized and adsorbed, as illustrated in FIG. 4A, 5 H₂O molecules are generated per 1 molecule of oxygen. On the other hand, in a case where H₂ gas is supplied as the hydrogen-containing reducing gas in a state where triethylindium is adsorbed and thereafter, the O₃ gas is supplied, as illustrated in FIG. 4B, only 1 H₂O molecule is generated per 1 molecule of oxygen.

In a case where the hydrogen-containing reducing gas is supplied simultaneously with the MO gas, furthermore, the thermal decomposition of the organometallic precursor may be promoted, and the effect of lowering the film formation temperature may be obtained.

Next, a yet another example of the first embodiment will be described.

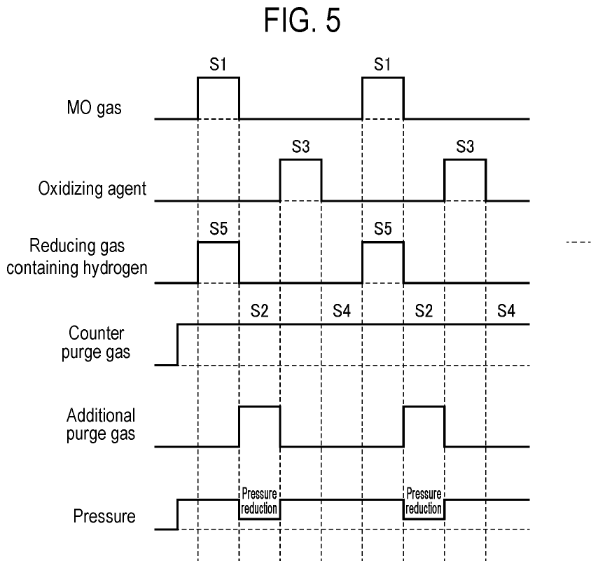

FIG. 5 is a timing chart illustrating a gas supply timing in yet another example of the film forming method according to the first embodiment. This example illustrates that the hydrogen-containing reducing gas, for example, the H₂ gas, and the oxidizing agent may be reliably prevented from flowing while being mixed with each other. When the oxidizing agent such as the O₃ gas is supplied in a state where, for example, the H₂ gas remains in the processing container, an explosive reaction may occur. Therefore, in this example, the purging of step S2 is strengthened to prevent such a reaction as much as possible. For example, a flow rate of the purge gas in step S2 may be increased, and/or exhaust may be strengthened in step S2. The example of FIG. 5 illustrates that, while constantly flowing the purge gas as a counter gas, an additional purge gas flows from a separate line to increase the flow rate of the purge gas in step S2, and a pressure is reduced only during the time period of step S2. In a case of film formation by the ALD method, the pressure reduction needs to be performed at a high speed since the time period of each step is short, and the exhaust may be strengthened, for example, by high-speed APC opening-degree control, high-speed gap control or the like, as will be described later.

### Second Embodiment

Next, a second embodiment will be described.

In the present embodiment, a multi-element metal oxide film, which includes a plurality of metal oxide films respectively containing different metals, is basically formed by the ALD method in a state where a substrate is accommodated in a processing container. Taking a ternary alloy oxide film as an example, there are provided a first operation of forming a first metal oxide film by ALD, a second operation of forming a second metal oxide film by ALD, and a third operation of forming a third metal oxide film by ALD. Each operation includes a step of supplying a MO gas, a step of purging a residual gas after the step of supplying the MO gas, a step of supplying an oxidizing agent to a substrate, and subsequently, a step of purging a residual gas, which are basically similar to those in the first embodiment. Then, these steps are repeated a desired number of cycles in each operation, and the first operation to the third operation are repeated a desired number of cycles. Further, in each cycle, at least one of the first operation, the second operation, or the third operation includes a step of supplying a hydrogen-containing reducing gas to the substrate simultaneously with the step of supplying the MO gas.

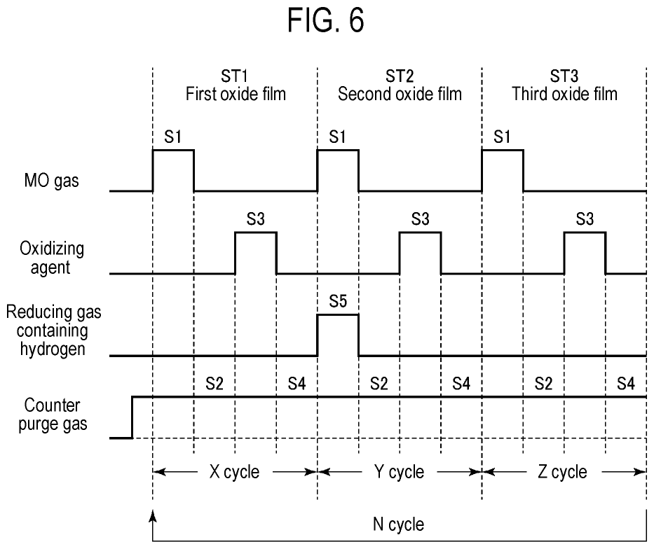

FIG. 6 is a timing chart illustrating a gas supply timing in an example of the film forming method according to the second embodiment. The example of FIG. 6 illustrates that the ternary metal oxide film is formed.

As illustrated in FIG. 6, the film forming method includes first operation ST1 of forming a first metal oxide film, second operation ST2 of forming a second metal oxide film, and third operation ST3 of forming a third metal oxide film. Each operation includes steps S1 to S4 similar to those of the first embodiment, and these steps are repeated X cycles in first operation ST1, repeated Y cycles in second operation ST2, and repeated Z cycles in third operation ST3. Furthermore, these operations ST1 to ST3 are repeated N cycles. Thus, a ratio and film thickness of each oxide film may be controlled. Further, in this example, in second operation ST2, the supply of the hydrogen-containing reducing gas in step S5 is performed simultaneously with the supply of the MO gas in step S1.

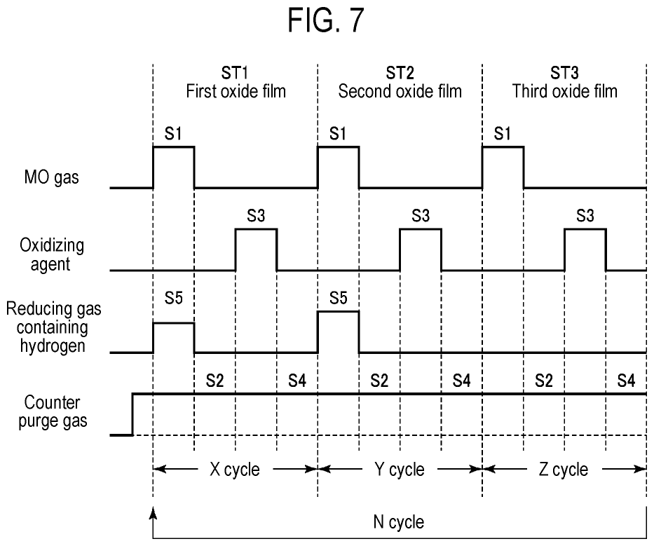

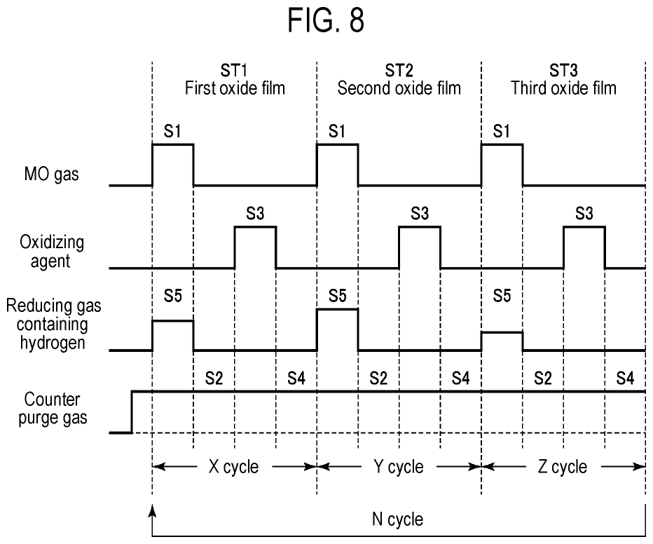

FIG. 7 illustrates an example in which step S5 is performed in first operation ST1 and second operation ST2, and FIG. 8 illustrates an example in which step S5 is performed in all of first operation ST1 to third operation ST3. In these cases, as illustrated in FIGS. 7 and 8, the supply amount of the hydrogen-containing reducing gas may be different in each operation.

Also in the present embodiment, by the step of supplying the hydrogen-containing reducing gas, as in the first embodiment, the effect of reducing impurities may be obtained, and the effect of improving the reactivity of the substrate surface with the oxidizing agent as well as the effect of restricting an amount of generated H₂O may be obtained due to a change from a CHₓ-termination surface to a H-termination surface. These effects may be obtained not only when the organometallic precursor and the hydrogen-containing reducing gas are simultaneously supplied, but also when they are sequentially supplied similarly to the example of FIG. 2 according to the first embodiment.

In addition, as described above, by performing the step of supplying the hydrogen-containing reducing gas to the substrate simultaneously with the step of supplying the organometallic precursor, the effect of promoting a thermal decomposition of the organometallic precursor to lower the film formation temperature may be similarly obtained. In the present embodiment, with the effect of lowering the film formation temperature, the film formation temperature of each metal oxide film may be made uniform when forming the multi-element metal oxide film by the ALD method as described below.

The formation of the multi-element metal oxide film by the ALD method as in the present embodiment may be performed in the same processing container and at the same temperature from the viewpoint of a tact time. Meanwhile, in the ALD method, the temperature range (ALD window) in which the precursor is saturated and adsorbed and the film formation rate (film thickness) is constant corresponds to an optimum film formation temperature at which the concentration of impurities becomes lower. However, since the ALD window greatly depends on the used precursor, the optimum film formation temperature of each of the metal oxide films constituting the multi-element metal oxide film may be different. For this reason, in the present embodiment, in at least one of the first operation, the second operation, or the third operation, the step of supplying the hydrogen-containing reducing gas to the substrate is performed simultaneously with the step of supplying the MO gas in each cycle, thereby promoting the thermal decomposition of the organometallic precursor to lower the film formation temperature. Accordingly, by simultaneously supplying the hydrogen-containing reducing gas and the MO gas to lower the film formation temperature when forming the metal oxide film having a high temperature range of the ALD window, it is possible to appropriately perform the formation of the multi-element metal oxide film by ALD at the same temperature. In addition, as in the first embodiment, the expression “simultaneously” also encompasses a case where a supply period of the organometallic precursor and a supply period of the hydrogen-containing reducing gas partially coincide with each other.

Next, a specific example of the second embodiment will be described.

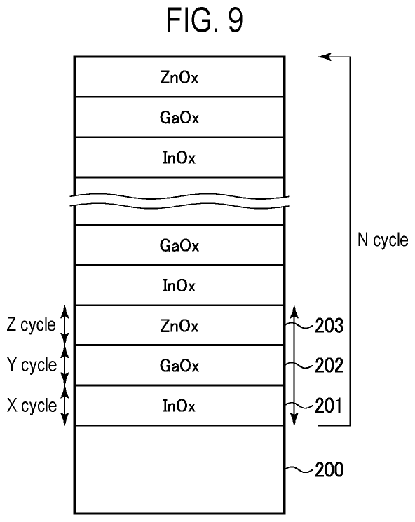

Here, an InGaZnO film (IGZO film), which is a thin oxide semiconductor film made of InOₓ, GaOₓ, and ZnOₓ, will be described as the multi-element metal oxide film by way of example. For example, when the first metal oxide film is InOₓ, the second metal oxide film is GaOₓ, and the third metal oxide film is ZnOₓ, the IGZO film is formed by the ALD method as illustrated in FIG. 9. That is, steps S1 to S4 above are repeated X cycles, Y cycles, and Z cycles, respectively, such that a stack of an InOₓ film 201, a GaOₓ film 202, and a ZnOₓ film 203 is formed on a substrate 200 having an oxide film (SiO₂ film) formed on the surface thereof. Then, assuming that the formation of this stack is one cycle, N cycles are repeated to form the IGZO film having a desired film thickness. As the organometallic precursor, for example, triethylindium, triethylgallium, and diethylzinc may be used.

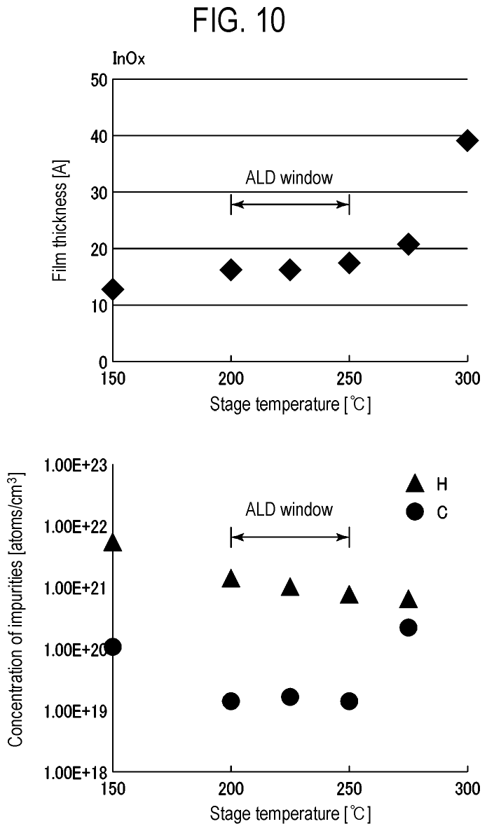

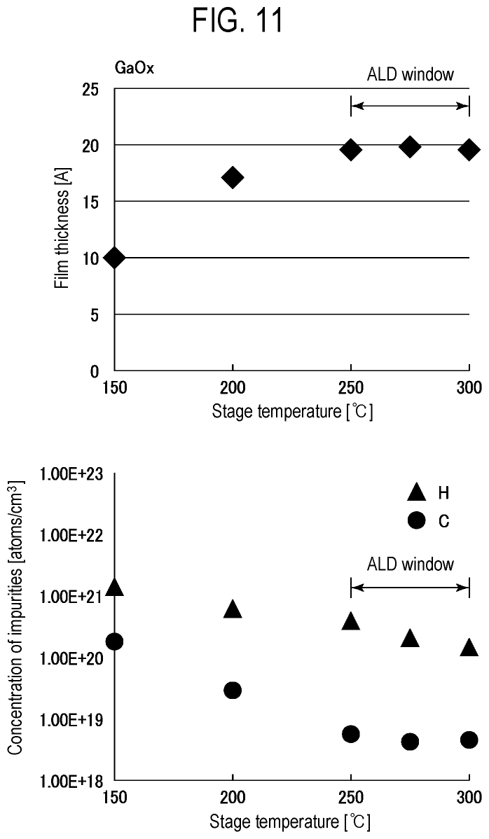

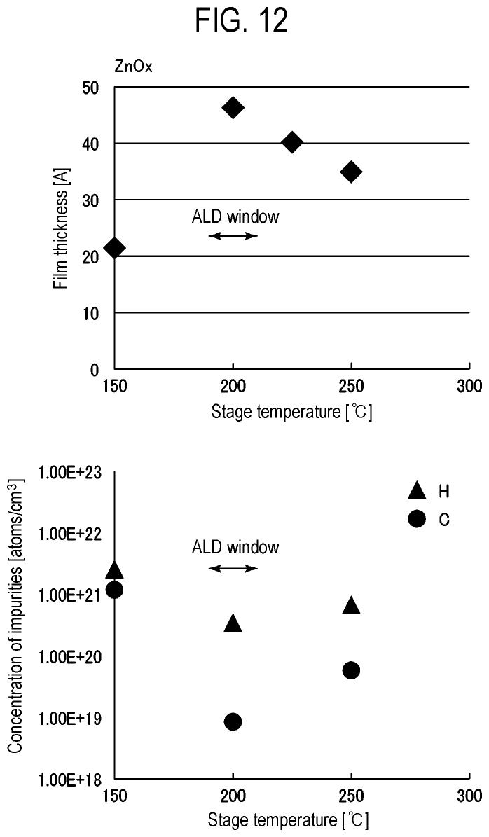

FIGS. 10 to 12 are diagrams illustrating a relationship between a substrate temperature and a film thickness, and a relationship between the substrate temperature and a concentration of impurities when forming the InOₓ film, the GaOₓ film, and the ZnOₓ film by a normal ALD method. The substrate temperature corresponds to a temperature of a stage on which the substrate is placed. Further, the concentration of impurities corresponds to a concentration of hydrogen (H) and carbon (C). Here, triethylindium, triethylgallium, and diethylzinc are used as an organic In precursor, an organic Ga precursor, and an organic Zn precursor which are the organometallic precursor, and the O₃ gas is used as the oxidizing agent. As described above, the ALD window, which is the temperature range in which the film formation rate becomes constant and the concentration of impurities is low, corresponds to the optimum film formation temperature suitable for ALD. Since the film formation rate is proportional to the film thickness, as illustrated in FIGS. 10 to 12, the temperature range of the ALD window is about 200 to 250 degrees C. for the InOₓ film, is about 250 to 300 degrees C. for the GaOₓ film, and is about 200 degrees C. for the ZnOₓ film. As described above, since the optimum film formation temperatures of the InOₓ film, the GaOₓ film, and the ZnOₓ film are different, optimum film formation is difficult when forming the IGZO film at the same temperature by ALD.

In contrast, for example, when forming the GaOₓ film which is the second oxide film, as illustrated in FIG. 6, by simultaneously supplying a Ga raw material gas and the hydrogen-containing reducing gas, for example, the H₂ gas, the thermal decomposition of the organometallic precursor may be promoted during the formation of the GaOₓ film, and thus the temperature range of the ALD window may be lowered. Thus, during the formation of the IGZO film, the optimum film formation temperature of each metal oxide film may be made uniform, and the IGZO film may be formed by the ALD-based optimum film formation at the same temperature.

In addition to forming the GaOₓ film which is the second oxide film, even when forming the InOₓ film which is the first oxide film, the film formation temperature of the InOₓ film, which has a higher temperature range of the ALD window than that of the ZnOₓ film, may also be lowered by simultaneously supplying an In raw material gas and the hydrogen-containing reducing gas. In this case, the IGZO film may be formed under more appropriate conditions by optimizing an amount of the hydrogen-containing reducing gas when forming the InOₓ film, which may be formed at a lower temperature than the GaOₓ film, to be smaller than an amount of the hydrogen-containing reducing gas when forming the GaOₓ film.

Further, the hydrogen-containing reducing gas may be supplied during the formation of all of the InOₓ film, the GaOₓ film, and the ZnOₓ film. Thus, the effect of reducing impurities and the effect of reducing H₂O may be obtained when forming all of the metal oxide films, and the film formation temperature may be lowered as a whole. Then, by optimizing the amount of the hydrogen-containing reducing gas when forming each metal oxide film, the optimum film formation temperature of each metal oxide film may be made uniform, and the IGZO film may be formed by the ALD-based optimum film formation at the same temperature.

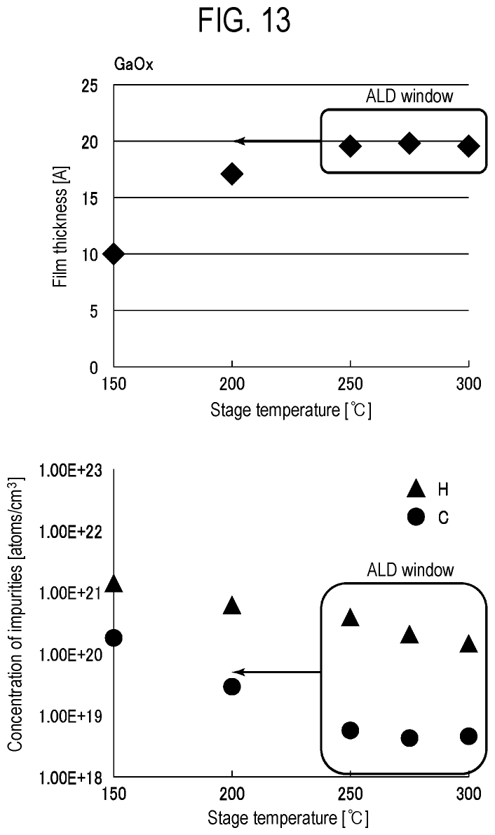

The effect of lowering the film formation temperature by the hydrogen-containing reducing gas as described above may be verified with activation energy. For example, in a case where triethylgallium is used when forming the GaOₓ film, the activation energy for the bond dissociation of ethyl groups is +2.77 eV, whereas the activation energy for a reaction with hydrogen is +1.59 eV. Accordingly, by simultaneously supplying the triethylgallium gas and the hydrogen-containing reducing gas, for example, the H₂ gas, the thermal decomposition of triethylgallium may be promoted, and thus, as illustrated in FIG. 13, the temperature range of the ALD window, that is, the film formation temperature, may be lowered. In addition, when using triethylindium and diethylzinc, the activation energies for the bond dissociation of ethyl groups are +2.32 eV and 2.07 eV, respectively. The thermal decomposition is prone to occur in the order of Zn (diethylzinc)>In (triethylindium)>Ga (triethylgallium). Further, the activation energies for reactions of triethylindium and diethylzinc with hydrogen are +1.56 eV and 1.82 eV, respectively. Thus, it can be seen that the thermal decomposition of triethylindium and diethylzinc may be promoted by the hydrogen-containing reducing gas, for example, the H₂ gas.

In addition, in this example, it is needless to say that basic effects such as the effect of reducing impurities as described above may be obtained by performing the step of supplying the hydrogen-containing reducing gas when forming at least one of the InOₓ film, the GaOₓ film, and the ZnOₓ film.

### Film Forming Apparatus

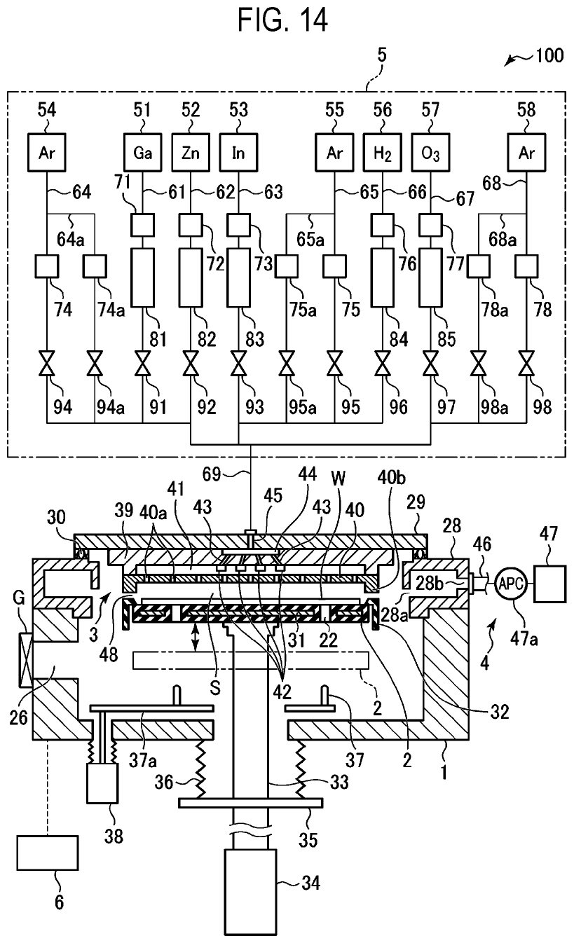

Next, an example of a film forming apparatus capable of carrying out the embodiments of the film forming method as described above will be described. FIG. 14 is a cross-sectional view illustrating an example of the film forming apparatus. Here, the film forming apparatus, which forms an IGZO film by using an organic Ga precursor, an organic Zn precursor, and an organic In precursor as the organometallic precursor, the O₃ gas as the oxidizing agent, the Ar gas as the purge gas, and the H₂ gas as the hydrogen-containing reducing gas, will be described by way of example.

A film forming apparatus 100 includes a chamber 1 which is the processing container, a susceptor (stage) 2, a shower head 3, an exhauster 4, a processing gas supply mechanism 5, and a controller 6.

The chamber 1, which is the processing container, is made of a substantially cylindrical metal. The chamber 1 is formed in a sidewall portion thereof with a loading/unloading port 26 for loading or unloading a substrate W into or from a vacuum transfer chamber (not illustrated) by a transfer mechanism (not illustrated). The loading/unloading port 26 is capable of being opened/closed by a gate valve G.

An annular exhaust duct 28 having a rectangular cross section is provided on a main body of the chamber 1. A slit 28a is formed along an inner peripheral surface of the exhaust duct 28. Further, an exhaust port 28b is formed in an outer wall of the exhaust duct 28. A ceiling wall 29 is provided at an upper surface of the exhaust duct 28 so as to close an upper opening of the chamber 1. A gap between the ceiling wall 29 and the exhaust duct 28 is hermetically sealed with a seal ring 30.

The susceptor 2, which is the stage, is provided to place the substrate W thereon within the chamber 1. The susceptor 2 has a disc shape with a size corresponding to the substrate W and is provided horizontally. The susceptor 2 is supported by a support member 33. A heater 31 is embedded in the susceptor 2 for heating the substrate W. The heater 31 is powered by a heater power supply (not illustrated) to generate heat. Then, the substrate W is controlled to a desired temperature by controlling the output of the heater 31. A ceramic cover member 32 is provided on the susceptor 2 so as to cover an outer peripheral region of a substrate placement surface and a lateral surface thereof

The support member 33, which supports the susceptor 2, extends downward of the chamber 1 from the center of a bottom surface of the susceptor 2 through a hole formed in a bottom wall of the chamber 1, and a lower end thereof is connected to a lifting mechanism 34 such that the susceptor 2 may be moved up and down by the lifting mechanism 34 via the support member 33 between a processing position indicated by a solid line in FIG. 14 and a transfer position as indicated by a two-dot dashed line below the processing position, at which the substrate may be transferred. Further, the lifting mechanism 34 is movable up and down at a high speed during purging. The chamber 1 is provided with a flange portion 35 at a position below the support member 33, and a bellows 36 is provided between the bottom surface of the chamber 1 and the flange portion 35. The bellows 36 serves to isolate an internal atmosphere of the chamber 1 from an ambient air and to be flexible with the vertical movement of the susceptor 2.

Three (only two illustrated) support pins 37 are provided in the vicinity of the bottom surface of the chamber 1 so as to protrude upward from a lifting plate 37a. The support pins 37 may be moved up and down via the lifting plate 37a by a lifting mechanism 38 provided below the chamber 1. The support pins 37 are inserted through respective through-holes 22 provided in the susceptor 2 positioned at the transfer position, so as to be able to move up and down from the upper surface of the susceptor 2. Thus, the substrate W is transferred between the substrate transfer mechanism (not illustrated) and the susceptor 2.

The shower head 3 supplies a processing gas into the chamber 1 in the form of a shower. The shower head 3 is provided in an upper portion of the chamber 1 so as to face the susceptor 2, and has substantially the same diameter as that of the susceptor 2. The shower head 3 includes a main body portion 39 fixed to the ceiling wall 29 of the chamber 1 and a shower plate 40 connected under the main body portion 39. A gas diffusion space 41 is defined between the main body portion 39 and the shower plate 40.

A plurality of gas dispersing members 42 are provided within the gas diffusion space 41. A plurality of gas discharge holes are formed around the gas dispersing members 42. The gas dispersing member 42 is connected to one end of each of a plurality of gas supply paths 43 provided in the main body portion 39. The other end of the gas supply path 43 is connected to a diffuser 44 formed in a central portion of the upper surface of the main body portion 39. Further, a gas introduction hole 45 is provided in a central portion of the main body portion 39 so as to penetrate the diffuser 44 from the upper surface of the main body portion 39.

An annular protrusion 40b is formed on a peripheral portion of the shower plate 40 so as to protrude downward. A gas discharge hole 40a is formed in a flat surface of the shower plate 40 inside the annular protrusion 40b. In a state where the susceptor 2 is present at the processing position, a processing space S is defined between the shower plate 40 and the susceptor 2. An annular gap 48 is formed between an upper surface of the cover member 32 of the susceptor 2 and the annular protrusion 40b which are adjacent to each other

The exhauster 4 includes an exhaust pipe 46 connected to the exhaust port 28b of the exhaust duct 28, an exhaust mechanism 47 connected to the exhaust pipe 46 and including a vacuum pump, and an automatic pressure control valve (APC) 47a provided in the exhaust pipe. During processing, the gas inside the chamber 1 reaches the exhaust duct 28 through the slit 28a, and is discharged through the exhaust pipe 46 by the exhaust mechanism 47 of the exhauster 4 from the exhaust duct 28. At this time, an internal pressure of the chamber 1 is controlled by an opening degree of the automatic pressure control valve (APC) 47a.

The processing gas supply mechanism 5 includes a Ga raw material gas source 51, a Zn raw material gas source 52, an In raw material gas source 53, a H₂ gas source 56, an O₃ gas source 57, a first Ar gas source 54, a second Ar gas source 55, and a third Ar gas source 58. The Ga raw material gas source 51 vaporizes an organic Ga precursor, for example, triethylgallium, to supply a Ga raw material gas. The Zn raw material gas source 52 vaporizes an organic Zn precursor, for example, diethylzinc, to supply a Zn raw material gas. The In raw material gas source 53 vaporizes an organic In precursor, for example, triethylindium, to supply an In raw material gas. The O₃ gas source 57 generates an O₃ gas from an O₂ gas by an ozonizer. Each of the first Ar gas source 54, the second Ar gas source 55, and the third Ar gas source 58 supplies an Ar gas as a purge gas.

The Ga raw material gas source 51, the Zn raw material gas source 52, the In raw material gas source 53, the H₂ gas source 56, and the O₃ gas source 57 are connected to one ends of a Ga raw material gas supply line 61, a Zn raw material gas supply line 62, an In raw material gas supply line 63, a H₂ gas supply line 66, and an O₃ gas supply line 67, respectively.

The first Ar gas source 54, the second Ar gas source 55, and the third Ar gas source 58 are connected to one ends of a first continuous Ar gas supply line 64, a second continuous Ar gas supply line 65, and a third continuous Ar gas supply line 68, respectively. The first continuous Ar gas supply line 64, the second continuous Ar gas supply line 65, and the third continuous Ar gas supply line 68 are continuously supplied with the Ar gas as a counter purge gas during processing.

The other end of the Ga raw material gas supply line 61 is connected to the Zn raw material gas supply line 62, and the other end of the first continuous Ar gas supply line 64 is connected to the Zn raw material gas supply line 62 via the Ga raw material gas supply line 61. The other end of the second continuous Ar gas supply line 65 is connected to the In raw material gas supply line 63. The other end of the H₂ gas supply line 66 is connected to the In raw material gas supply line 63 via the second continuous Ar gas supply line 65. The other end of the third continuous Ar gas supply line 68 is connected to the O₃ gas supply line 67. The other ends of the Zn raw material gas supply line 62, the In raw material gas supply line 63, and the O₃ gas supply line 67 are joined in a junction line 69. The junction line 69 is connected to the gas introduction hole 45.

A first flash purge line 64a is branched in the first continuous Ar gas supply line 64, a second flash purge line 65a is branched in the second continuous Ar gas supply line 65, and a third flash purge line 68a is branched in the third continuous Ar gas supply line 68. Further, lower ends of the first flash purge line 64a, the second flash purge line 65a, and the third flash purge line 68a are joined with the first continuous Ar gas supply line 64, the second continuous Ar gas supply line 65, and the third continuous Ar gas supply line 68, respectively. The first flash purge line 64a, the second flash purge line 65a, and the third flash purge line 68a are lines for supplying a large amount of Ar gas during purging to perform flash purging.

The Ga raw material gas supply line 61 includes a flow meter 71, a buffer tank 81, and a valve 91 sequentially provided from the upstream side thereof. The Zn raw material gas supply line 62 includes a flow meter 72, a buffer tank 82, and a valve 92 sequentially provided from the upstream side thereof. The In raw material gas supply line 63 includes a flow meter 73, a buffer tank 83, and a valve 93 sequentially provided from the upstream side thereof. The H₂ gas supply line 66 includes a flow controller 76, a buffer tank 84, and a valve 96 sequentially provided from the upstream side thereof. The O₃ gas supply line 67 includes a flow controller 77, a buffer tank 85, and a valve 97 sequentially provided from the upstream side thereof. The buffer tanks 81 to 85 temporarily store respective gases. The gases are stored in the respective buffer tanks so that internal pressures of the respective buffer tanks are increased. Thereafter, the gases stored in the respective buffer tanks are supplied into the chamber 1 so that a large flow rate of gases may be supplied into the chamber 1.

The first Ar gas source 54, the second Ar gas source 55, and the third Ar gas source 58 include a flow controller 74 and a valve 94, a flow controller 75 and a valve 95, and a flow controller 78 and a valve 98, which are sequentially provided from the upstream sides thereof, respectively. Further, the first flash purge line 64a, the second flash purge line 65a, and the third flash purge line 68a include a flow controller 74a and a valve 94a, a flow controller 75a and a valve 95a, and a flow controller 78a and a valve 98a, which are sequentially provided from the upstream sides thereof, respectively.

The valves 91, 92, 93, 96, 97, 94a, 95a, and 98a function as an ALD valve for gas switching during ALD, and are configured as high-speed valves that is capable of being opened/closed at a high speed.

Since triethylgallium, diethylzinc, and triethylindium used as the organic Ga precursor, the organic Zn precursor, and the organic In precursor are liquid at room temperature, the Ga raw material gas source 51, the Zn raw material gas source 52, and the In raw material gas source 53 include a mechanism for vaporizing a liquid raw material. For example, the Ga raw material gas source includes a raw material container for storing the organic Ga precursor in a liquid state, a heating mechanism for heating the raw material container, and a carrier gas supply line for supplying a carrier gas into the raw material container. Further, the Ga raw material gas supply line 61 described above is inserted into the raw material container, and the Ga raw material gas is transferred by the carrier gas inside the Ga raw material gas supply line 61. A flow rate of the Ga raw material gas is controlled by a flow controller provided in the carrier gas supply line. The Zn raw material gas source 52 and the In raw material gas source 53 are similar to each other in configuration.

In addition, the first to third flash purge lines 64a, 65a, and 68a and the buffer tanks 81 to 85 are not essential.

The controller 6 is configured with a computer, and includes a main controller equipped with a CPU, an input device, an output device, a display device, and a storage device (storage medium). The main controller controls, for example, the opening and closing of the valve, the flow rate of the gas by the flow controller, the opening degree of the pressure control valve (APC), the output of the heater that heats the substrate W, and the like. These controls are executed according to a processing recipe stored in the storage medium built into the storage device.

Next, an example of a film forming procedure using the film forming apparatus 100 configured as described above will be described. To set the temperature of the substrate W placed on the susceptor 2 to a desired temperature in advance, the controller 6 controls heating by the heater 31 to control the temperature of the susceptor 2.

In this state, first, the gate valve G is opened, and the substrate W is loaded into the chamber 1 from the vacuum transfer chamber by the transfer device (both not illustrated) and is placed on the susceptor 2.

After placing the substrate W and retracting the transfer device, the gate valve G is closed and the susceptor 2 is moved up to the processing position. Subsequently, the interior of the chamber 1 is exhausted by the exhauster 4, and the valves 94, 95 and 98 are opened to continuously supply the Ar gas into the processing space S of the chamber 1 through the first continuous Ar gas supply line 64, the second continuous Ar gas supply line 65, and the third continuous Ar gas supply line 68.

Then, an InOₓ film, a GaOₓ film, and a ZnOₓ film are successively formed using the ALD method as described below while keeping the Ar gas continuously supplied. This film formation is repeated N cycles. The formation of each of the InOₓ film, the GaOₓ film, and the ZnOₓ film by the ALD method is basically performed in the same order.

First, the formation of the InOₓ film will be described.

As described above, in a state where the Ar gas is continuously supplied, the valve 93 is opened to supply the In raw material gas to the processing space S in the chamber 1 from the In raw material gas source 53 through the In raw material gas supply line 63 (step S1). The In raw material gas is generated by vaporizing triethylindium as the organic In precursor. In step S1, the In raw material gas is adsorbed onto the surface of the substrate W. At this time, the In raw material gas is temporarily stored in the buffer tank 83, and is supplied into the chamber 1 after the internal pressure of the buffer tank 83 is increased.

Subsequently, the valve 93 is closed to stop the In raw material gas, and the interior of the processing space S of the chamber 1 is purged by the Ar gas that is being continuously supplied (step S2).

Subsequently, the valve 97 is opened to supply the O₃ gas from the O₃ gas source 57 to the processing space S in the chamber 1 through the O₃ gas supply line 67 (step S3). Thus, a reaction of the In raw material gas adsorbed onto the substrate and the O₃ gas occurs. The O₃ gas is temporarily stored in the buffer tank 85, and is supplied into the chamber 1 after the internal pressure of the buffer tank 85 is increased.

Subsequently, the valve 97 is closed to stop the O₃ gas, and the interior of the processing space S of the chamber 1 is purged by the Ar gas that is being continuously supplied as the counter purge gas (step S4).

By sequentially performing steps S1 to S4 above, a thin InOₓ unit film is formed, and by repeating these steps predetermined X cycles, the InOₓ film having a desired thickness is formed.

Next, the formation of the GaOₓ film will be described.

Similarly, in a state where the Ar gas is continuously supplied, the valve 91 is opened to supply the Ga raw material gas to the processing space S in the chamber 1 from the Ga raw material gas source 51 through the Ga raw material gas supply line 61 (step S1). The Ga raw material gas is generated by vaporizing triethylgallium as the organic Ga precursor. In step S1, the Ga raw material gas is adsorbed onto the surface of the substrate W. At this time, the Ga raw material gas is temporarily stored in the buffer tank 81, and is supplied into the chamber 1 after the internal pressure of the buffer tank 81 is increased.

Simultaneously with this step S1, the valve 96 is opened to supply the H₂ gas from the H₂ gas source 56 to the processing space S in the chamber 1 through the H₂ gas supply line 66 (step S5). At this time, the H₂ gas is temporarily stored in the buffer tank 84, and is supplied into the chamber 1 after the internal pressure of the buffer tank 84 is increased.

By simultaneously performing steps S1 and S5, the thermal decomposition of, for example, triethylgallium, which is the organic Ga precursor, may be promoted, and the film formation temperature may be lowered.

After steps S1 and S5 are performed, the valve 91 and the valve 96 are closed to stop the supply of the Ga raw material gas and the H₂ gas, respectively, and the interior of the processing space S of the chamber 1 is purged (step S2). In step S2, purging is strengthened so as to prevent mixing of the H₂ gas remaining in the chamber 1 and the O₃ gas which is to be supplied subsequently as much as possible. Specifically, in addition to the continuously supplied Ar gas, the Ar gas (flash purge Ar gas) is supplied from the first flash purge line 64a, the second flash purge line 65a, and the third flash purge line 68a by opening the valves 94a, 95a and 98a, so that the flow rate of the purge gas is increased. Further, in addition to this, the internal pressure of the chamber 1 is reduced only during the time period of step S2 by increasing the opening degree of the automatic pressure control valve (APC) 47a, or by increasing the gap between the susceptor 2 and the shower head 3 by the lifting mechanism 34. Since the time periods of steps S1 to S4 in ALD are short, it is necessary to perform high-speed APC control and high-speed gap control in order to reduce the pressure in step S2.

Subsequently, the valves 94a, 95a and 98a are closed, and the valve 97 is opened to supply the O₃ gas to the processing space S in the chamber 1 from the O₃ gas source 57 through the O₃ gas supply line 67, as in the formation of the InOₓ film (step S3). Thus, a reaction of the Ga raw material gas adsorbed onto the substrate and the O₃ gas occurs.

Subsequently, the valve 97 is closed to stop the supply of the O₃ gas, and the interior of the processing space S of the chamber 1 is purged by the Ar gas that is being continuously supplied (step S4).

By sequentially performing steps S1 to S4 above and performing step S5 between steps S1 to S4 as described above, a thin GaOₓ unit film is formed. By repeating these steps predetermined Y cycles, the GaOₓ film having a desired film thickness is formed.

Next, the formation of the ZnOₓ film will be described.

Similarly, in a state where the Ar gas is continuously supplied, the valve 92 is opened to supply the Zn raw material gas to the processing space S in the chamber 1 from the Zn raw material gas source 52 through the Zn raw material gas supply line 62 (step S1). The Zn raw material gas is generated by vaporizing diethylzinc which is the organic Zn precursor. In step 51, the Zn raw material gas is adsorbed onto the surface of the substrate W. At this time, the Zn raw material gas is temporarily stored in the buffer tank 82, and is supplied into the chamber 1 after the internal pressure of the buffer tank 82 is increased.

Subsequently, the valve 92 is closed to stop the supply of the Zn raw material gas, and the interior of the processing space S of the chamber 1 is purged by the Ar gas that is being continuously supplied (step S2).

Subsequently, the valve 97 is opened to supply the O₃ gas to the processing space S in the chamber 1 from the O₃ gas source 57 through the O₃ gas supply line 67, as in the formation of the InOₓ film (step S3). Thus, a reaction of the Zn raw material gas adsorbed onto the substrate and the O₃ gas occurs.

Subsequently, the valve 97 is closed to stop the supply of the O₃ gas, and the interior of the processing space S of the chamber 1 is purged by the Ar gas that is being continuously supplied (step S4).

By sequentially performing steps S1 to S4 above, a thin ZnOₓ unit film is formed. By repeating these steps predetermined Z cycles, the ZnOₓ film having a desired thickness is formed.

After the formation of the IGZO film is completed by performing the formation of the InOₓ film, the GaOₓ film, and the ZnOₓ film N cycles, the interior of the chamber 1 is purged with the Ar gas, and the susceptor 2 is lowered to the transfer position. Subsequently, the gate valve G is opened, and the substrate W on the susceptor 2 is discharged from the chamber 1 by the transfer device entering to the chamber 1 from the vacuum transfer chamber.

The example of forming the IGZO film by the sequence illustrated in FIG. 6 has been described above, but the IGZO film may also be formed by the sequence illustrated in FIGS. 7 and 8.

### Other Applications

Although the embodiments have been described above, the embodiments disclosed herein should be considered to be exemplary and not restrictive in all respects. The above embodiments may be omitted, replaced, or modified in various ways without departing from the scope and spirit of the appended claims.

For example, the film forming apparatus illustrated in FIG. 14 is merely given by way of example, and may be a single-wafer-type film forming apparatus having a different structure from FIG. 14, or may be a batch-type film forming apparatus that forms a film on a plurality of substrates at once. Further, the film forming apparatus for forming the IGZO film which is the multi-element metal oxide film has been described by way of example, the present disclosure is not limited thereto, and the film forming apparatus may form a single metal oxide film by way of example.

According to the present disclosure in some embodiments, there are provided a film forming method and a film forming apparatus which are capable of forming a metal oxide film with few impurities.

What is claimed is:

1. A film forming method of forming a metal oxide film on a substrate in a processing container, the film forming method comprising:
supplying a raw material gas containing an organometallic precursor into the processing container;
removing a residual gas remaining in the processing container after the supplying the raw material gas;
subsequently, supplying an oxidizing agent that oxidizes the raw material gas into the processing container;
removing a residual gas remaining in the processing container after the supplying the oxidizing agent; and
supplying a hydrogen-containing reducing gas into the processing container, simultaneously with the supplying the raw material gas or sequentially after the supplying the raw material gas.

2. The film forming method of claim 1, wherein the supplying the raw material gas, the removing the residual gas after the supplying the raw material gas, the supplying the oxidizing agent, and the removing the residual gas after the supplying the oxidizing agent are repeated a plurality of cycles, and the supplying the hydrogen-containing reducing gas is performed in each of the plurality of cycles.

3. The film forming method of claim 1, wherein the removing the residual gas after the supplying the raw material gas further removes a residual gas remaining after the supplying the hydrogen-containing reducing gas.

4. The film forming method of claim 1, wherein the supplying the hydrogen-containing reducing gas desorbs an organic ligand of the organometallic precursor.

5. The film forming method of claim 4, wherein the organic ligand of the organometallic precursor is an alkyl group, and the supplying the hydrogen-containing reducing gas separates the alkyl group from the organometallic precursor adsorbed onto the substrate to terminate hydrogen from the organometallic precursor and suppresses H₂O from being generated in the supplying the oxidizing agent.

6. A film forming method of forming, on a substrate in a processing container, a multi-element metal oxide film including a plurality of metal oxide films respectively containing different metals, the film forming method comprising:
a plurality of operations of forming the plurality of metal oxide films, respectively,
wherein each of the plurality of operations includes:
supplying a raw material gas containing an organometallic precursor into the processing container;
removing a residual gas remaining in the processing container after the supplying the raw material gas;
subsequently, supplying an oxidizing agent that oxidizes the raw material gas into the processing container; and
removing a residual gas remaining in the processing container after the supplying the oxidizing agent, and
wherein at least one of the plurality of operations includes supplying a hydrogen-containing reducing gas into the processing container, simultaneously with the supplying the raw material gas or sequentially after the supplying the raw material gas.

7. The film forming method of claim 6, wherein, among the plurality of operations, in the operation including the supplying the hydrogen-containing reducing gas, the supplying the raw material gas, the removing the residual gas after the supplying the raw material gas, the supplying the oxidizing agent, and the removing the residual gas after the supplying the oxidizing agent are repeated a plurality of cycles, and the supplying the hydrogen-containing reducing gas is performed in each of the plurality of cycles.

8. The film forming method of claim 7, wherein the plurality of operations are repeated a plurality of cycles.

9. The film forming method of claim 8, wherein the supplying the hydrogen-containing reducing gas is performed simultaneously with the supplying the raw material gas, and in the operation including the supplying the hydrogen-containing reducing gas, a film formation temperature of the plurality of metal oxide films is lowered so that an optimum film formation temperature of the multi-element metal oxide film is made uniform.

10. The film forming method of claim 9, wherein the plurality of metal oxide films are an InOₓ film, a GaOₓ film, and a ZnOₓ film, and the multi-element metal oxide film is an InGaZnO film.

11. The film forming method of claim 10, wherein an operation of forming the GaOₓ film includes the supplying the hydrogen-containing reducing gas, and the supplying the hydrogen-containing reducing gas is performed simultaneously with the supplying the raw material gas.

12. The film forming method of claim 10, wherein an operation of forming the GaOₓ film and an operation of forming the InOₓ film include the supplying the hydrogen-containing reducing gas, and the supplying the hydrogen-containing reducing gas is performed simultaneously with the supplying the raw material gas.

13. The film forming method of claim 12, wherein an amount of the hydrogen-containing reducing gas in the supplying the hydrogen-containing reducing gas is smaller in the operation of forming the InOₓ film than in the operation of forming the GaOₓ film.

14. The film forming method of claim 13, wherein the removing the residual gas after the supplying the raw material gas further removes a residual gas remaining after the supplying the hydrogen-containing reducing gas.

15. The film forming method of claim 14, wherein a continuous purge gas is supplied into the processing container in a continuous manner while performing the supplying the raw material gas, the removing the residual gas after the supplying the raw material gas, the supplying the oxidizing agent, and the removing the residual gas after the supplying the oxidizing agent,
wherein the removing the residual gas after the supplying the raw material gas and the removing the residual gas after the supplying the oxidizing agent are performed by the continuous purge gas, and
wherein an additional purge gas is supplied in addition to the continuous purge gas during the removing the residual gas after the supplying the raw material gas.

16. The film forming method of claim 15, wherein a pressure in the processing container is reduced during the removing the residual gas after the supplying the raw material gas.

17. The film forming method of claim 16, wherein the supplying the hydrogen-containing reducing gas desorbs an organic ligand of the organometallic precursor.

18. The film forming method of claim 17, wherein the organic ligand of the organometallic precursor is an alkyl group, and the supplying the hydrogen-containing reducing gas separates the alkyl group from the organometallic precursor adsorbed onto the substrate to terminate hydrogen from the organometallic precursor and suppresses H₂O from being generated in the supplying the oxidizing agent.

19. The film forming method of claim 18, wherein the hydrogen-containing reducing gas is a hydrogen gas.

20. A film forming apparatus for forming a metal oxide film on a substrate, comprising:
a processing container in which the substrate is accommodated;
a stage provided in the processing container and configured to place the substrate thereon;
a gas supplier configured to supply a gas to the processing container;
an exhauster configured to exhaust an interior of the processing container; and
a controller,
wherein the controller controls the gas supplier and the exhauster so as to perform:
supplying a raw material gas containing an organometallic precursor into the processing container;
removing a residual gas remaining in the processing container after the supplying the raw material gas;
subsequently, supplying an oxidizing agent that oxidizes the raw material gas into the processing container;
removing a residual gas remaining in the processing container after the supplying the oxidizing agent; and
supplying a hydrogen-containing reducing gas into the processing container, simultaneously with the supplying the raw material gas or sequentially after the supplying the raw material gas.
